(19) United States
(12) Patent Application Publication
(10) Pub. No.: US 2014/0061832 A1
(43) Pub. Date: Mar. 6, 2014

(54) SURFACE PLASMON DEVICE

(71) Applicants: Alexandros Emboras, Grenoble (FR); Roch Espiau De Lamaestre, Grenoble (FR)

(72) Inventors: Alexandros Emboras, Grenoble (FR); Roch Espiau De Lamaestre, Grenoble (FR)

(73) Assignee: COMMISSARIAT A L'ENERGIE ATOMIQUE ET AUX ENERGIES ALTERNATIVES, Paris (FR)

(21) Appl. No.: 14/115,003

(22) PCT Filed: May 2, 2011
(86) PCT No.: PCT/IB2011/001492

§ 371 Date: Oct. 31, 2013

(51) Int. Cl. H01L 31/0224

(52) U.S. Cl. CPC H01L 31/0224
USPC 257/431

(57) ABSTRACT

The electro-optical device includes a semiconductor layer, a first metal layer and an electrical insulator layer disposed between the semiconductor layer and the first metal layer. The electrical insulator layer includes a silicon nitride layer so as to provide an interface between the first metal layer and the silicon nitride layer. The electro-optical device is configured to carry a plasmonic wave.

### BACKGROUND OF THE INVENTION

The invention generally relates to electro-optical devices suitable for integrated photonic applications, and more particularly to surface plasmon electro-optical devices.

### STATE OF THE ART

Metal layers are frequently used in electro-optical devices as photon waveguides. In some of these devices, gate contact needs to be metallic to allow the generation and the use of plasmon guided modes. Indeed, a Metal Insulator Semiconductor (MIS) stack can be used to manufacture various surface plasmon devices, such as electro-optical modulators, field effect light sources, etc.

An effective operation of plasmon electro-optical devices requires the metal layer to be placed close to the electrical charge accumulation or depletion regions. For example in patent application WO2009/120721, in which a plasmonic modulator is described, only a thin oxide layer separates the metal layer from the silicon active layer. In fact, the electro-optical device is comprised of a MIS stack. A 10 nm thick oxide was grown on the top surface of a 170 nm thick doped silicon membrane. The gate contact of the plasmonic device was formed by deposition of a 400 nm-thick silver layer onto the oxide layer.

In such devices a thin dielectric layer, here the oxide layer, allows the device to operate with a reasonable electric field (i.e. low power consumption). It also allows propagation of the plasmons at the metal layer surface, which is close to the semiconductor active layer.

Ideally for a large-scale integration, plasmon based devices have dimensions, materials and functionality compatible with common CMOS technology. In a CMOS foundry environment, thermal treatments are usually around 400° C. in conventional back end processes. At those temperatures, metal diffusion within the active region comprised of silicon and silicon oxide is extremely fast. This diffusion is detrimental to electro-optical device operation and performance.

No plasmon electro-optical device, comprising a MIS stack, has been disclosed with a solution to limit metal diffusion in the device's active zone. Indeed, these structures have been realized and studied for research purposes, neglecting the development aspect for large-scale integration and industrial production.

### SUMMARY OF THE INVENTION

In some manufacturing conditions, there is a need for plasmon electro-optical devices that are able, furthermore, to undergo heat treatments used in conventional CMOS technology, while having reasonable power consumption, and a satisfactory optical performance.

We tend to meet this need by providing an electro-optical device that comprises a semiconductor layer, a first metal layer, and an electrical insulator layer disposed between the semiconductor layer and the first metal layer. The electrical insulator layer comprises a silicon nitride layer so as to provide an interface between the first metal layer and the silicon nitride layer. Furthermore, the electro-optical device is configured to carry a plasmonic wave.

### BRIEF DESCRIPTION OF THE DRAWINGS

FIG. 1-A illustrates a cross sectional view of a MIS stack usable in surface plasmon devices according to the invention;

FIG. 1-B illustrates a cross sectional view of another MIS stack usable in surface plasmon device according to the invention;

FIG. 2 illustrates a comparison of statistical distributions of breakdown voltages for two different MIS stacks, with and without silicon nitride-based diffusion barrier; and

FIG. 3 illustrates statistical distributions of breakdown voltages for different MIS stacks with different diffusion barriers.

### DESCRIPTION OF A PREFERRED EMBODIMENT OF THE INVENTION

To perform an effective large-scale integration of electro-optical devices that operate using surface plasmon waves and that contain a MIS stack, it is preferable to use means that moderate the metal contamination.

It is therefore sought to incorporate into the structure of the surface plasmon device a diffusion barrier while minimizing the decrease in electrical and optical performances.

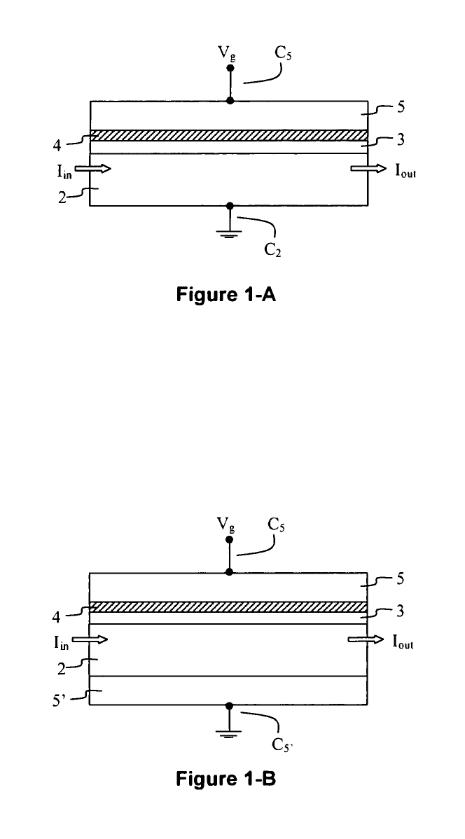

FIGS. 1-A and 1-B schematically illustrate two embodiments of structures usable in electro-optical devices, which tend to satisfy these constraints.

FIG. 1-A illustrates a stack that comprises a layer of semiconductor material 2 and a first metal layer 5. Between the semiconductor layer 2 and the first metal layer 5 is disposed an electrical insulator layer 3. In other words, the electro-optical device comprises a semiconductor layer 2, a first metal layer 5 and an electrical insulator layer 3 disposed between the semiconductor layer 2 and the first metal layer 5. The electrical insulator layer 3 also comprises a layer 4, in a specific material, so as to provide an interface between the first metal layer 5 and the layer 4. This interface is capable of carrying a plasmonic wave.

On the free surfaces of the metal layer 5 and the semiconductor layer 2, electrical contacts C₅ and C₂ can be formed. Thus, the semiconductor layer 2 and the metal layer 5 can be configured as electric contacts. To that electrical purpose the semiconductor layer 2 is preferably n-doped or p-doped with a concentration between 10¹⁶ at/cm³ and 10²¹ at/cm³. These electrical contacts may be subjected to different electric potentials. For example, the electrical contact C₂ can be connected to ground and electrical contact C₅ can be set at a positive electric potential V_{g}.

As illustrated in FIG. 1-B an additional metal layer can be included in the electro-optical device. A second metal layer 5′ is disposed adjacent the semiconductor layer 2 on the opposite side of the first metal layer 5, forming a contact C_{5′} that replaces the ground contact C₂ of FIG. 1-A. Thus, the first 5 and the second 5′ metal layers can be configured as electric contacts.

The semiconductor layer 2 can be made, for example, of silicon, germanium, a silicon-germanium alloy or another semiconductor material. Advantageously, the semiconductor layer 2 comprises silicon. Here, the layer is made of n-doped or p-doped silicon and in which impurity concentration is between 10¹⁶ at/cm³ and 10²¹ at/cm³.

Advantageously, the electrical insulator layer 3 comprises silicon oxide. Preferably, the first 5 and second 5′ metal layers comprise a material selected in the group consisting of noble metal: gold, silver, copper, and aluminum. Here, the electrical insulator layer 3 is made of silicon oxide and the metal layers 5 and 5′ are copper.

The electro-optical device comprising one of the structures illustrated in FIGS. 1-A and 1-B is configured to carry a plasmonic wave. For example, the electro-optical device can be a field effect light source. In this case, the electrical insulator layer can comprise emitters like nanocrystals. The application of an electric field across the MIS structure induces a charge carrier injection into emitters and thus light emission is performed. As a result a plasmonic wave can be generated.

The electro-optical device comprising the structure illustrated in FIG. 1-A and the electro-optical device comprising the structure illustrated in FIG. 1-B are, advantageously, configured to alter the propagation properties of a plasmonic wave in response to the application of an electrical field across, respectively, the first metal layer 5 and the semiconductor layer 2, and the first metal layer 5 and the second metal layer 5′.

Advantageously, the electro-optical device that include one of the two structures illustrated in FIGS. 1-A and 1-B, is an electro-optical modulator wherein an incident optical radiation Iᵢₙ is modulated into transmitted optical radiation Iₒᵤₜ. For example, the semiconductor layer 2 can comprise an optical input terminal (not illustrated in FIGS. 1-A and 1-B) for the incident optical radiation Iᵢₙ, and an optical output terminal (not illustrated in FIGS. 1-A and 1-B) for the transmitted optical radiation Iₒᵤₜ. The modulation is achieved by the application of an electric field to the MIS structure and the application of the incident optical radiation Iᵢₙ at the optical input terminal to provide a modulated optical radiation as a transmitted optical radiation Iₒᵤₜ at the optical output terminal; that in turn modulates the intensity or another parameter of the plasmonic modes, or another optical mode existing in the MIS stack. Indeed, the applied electric field will induce accumulation or depletion of carrier that will modulate, for example, the effective index of the plasmon mode. Therefore, the use of an electro-optical device, that include one of the two structures illustrated in FIGS. 1-A and 1-B, within an interferometric structure, like a mach-zehnder interferometer, will generate an intensity modulation.

Generally, conventional optical devices have dimensions of the order of the signal's wavelength. Consequently, they are larger than microelectronic devices manufactured in CMOS technology. However, surface plasmons are surface electromagnetic waves propagating along metal-dielectric interfaces. Because these surface plasmons exhibit small wavelengths and high local field intensities, optical confinement can scale to deep sub wavelength dimensions in surface plasmon-based devices. Therefore, the dimensions of these devices can be significantly reduced. This dimension reduction, allows the co-integration of optical and microelectronic components using CMOS technology. For example, the thicknesses of different insulator layers comprised in the structures illustrated in FIGS. 1-A and 1-B are less than 20 nm.

Preferably, the specific material of layer 4 is suitable for reducing metal contamination of chemical elements of layer 5 in the underlying layers, i.e.: it forms a diffusion barrier. This diffusion barrier is involved in the characteristics of the surface plasmon device; therefore it is desirable that it meets certain constraints that are required in such devices.

Ideally, the material of layer 4 is an effective metal diffusion barrier that is transparent to the propagation of photons and that has electrical characteristics allowing the device operation at low voltages.

An effective diffusion barrier should allow proper electrical operation of the MIS capacitor and should improve the electrical reliability of the device. In conventional plasmon based devices, MIS stacks do not include metal diffusion barriers. In CMOS technology, conventional metal diffusion barriers are based on titanium (Ti), titanium nitride (TiN), tantalum (Ta), and tantalum nitride (TaN). These materials can be considered as effective diffusion barriers. From an electric point of view, their use to prevent metal diffusion in a MIS stack can lead to an improved electric operation of the device. Nevertheless those materials are metallic and generate very high optical losses that prevent their use in surface plasmon devices.

Indeed, placing a transparent material layer in the vicinity of metal layer 5 and electrical insulator layer 3 can reduce the optical propagation losses of the plasmon and thereby improve the optical performance of the plasmon surface device. In fact, the minimization of metal-related optical losses is considered as a key issue of plasmon based devices. In the near infrared region, the optical losses of metals are proportional to their DC resistivity. In that respect, using copper, silver or gold, as a gate contact in plasmon based devices is very favorable. However, using Ti, TiN, Ta or TaN based layers as diffusion barriers will induce high optical losses. Indeed, these materials are known to be more resistive materials than copper or aluminum. The optical losses associated with such metallic diffusion barriers remain too high for electro-optical operation.

Other materials, such as electrical insulators, have been proposed to form metal diffusion barriers. To prevent contamination by copper, which is widely used in CMOS technology as an interconnect material, the use of dielectric layers as diffusion barriers was investigated in different research studies. For example, in paper [“Effect of film thickness on the breakdown temperature of atomic layer deposited ultrathin HfO₂ and Al₂O₃ diffusion barriers in copper metallization”—P. Majumder et al.—Journal of Crystal Growth, 309 (2007) 12-17], HfO₂ and Al₂O₃ diffusion barriers were investigated by studying Cu/barrier film/Si structures. Majumder et al. show that 1 and 2 nm-thicknesses of these diffusion barriers are capable of limiting the copper diffusion under certain conditions.

Another study, [“Passivation effect of silicon nitride against copper diffusion”—H. Miayazaki et al.—Journal of Applied Physics, 81 (12), 15 Jun. 1997], demonstrates that Low Pressure Chemical Vapor Deposition silicon nitride (LPCVD-SiN) can effectively suppress copper diffusion. In this work, Cu/LPCVD-SiN/SiO₂/Si structures were studied. The structural and electrical characterizations of these structures show that a 100 nm thickness of LPCVD-SiN can be used as an effective diffusion barrier for copper metallization.

It is important to note that all the structures studied in these papers were crafted experimentally for the sole purpose of studying the diffusion properties of copper metallization. There were no plans to use these stacks for real transistors, and even less for optical devices. Consequently, the diffusion requirements were much less stringent in the former than in the latter and related.

Moreover, in the research study cited above, the effect of HfO₂ and Al₂O₃ based diffusion barrier has been studied using two characterization techniques. The first technique was a classical four-point probe for sheet resistance measurements. This probe was used to measure sheet resistance of stacks containing a diffusion barrier layer as a function of annealing temperature. The second technique was an X-ray diffraction (XRD) analysis which was carried out to identify phase formations of compounds containing Cu and Si atoms in annealed stacks containing a diffusion barrier layer.

The use of XRD analysis allowed the detection of Cu₃Si compound formation. This compound requires the presence of a significant Cu atom concentration in a silicon layer. According to this study, XRD analysis can qualitatively detect the annealing temperature of the barrier film mechanical failure. Likewise, the four-point probe measurements are appreciable only in the presence of significant Cu atom diffusion in a silicon layer. Generally, these two characterization techniques detect Cu atoms penetration in the silicon layer with typically a ratio greater than 0.1%.

Therefore, these results could be available to realize diffusion barriers for interconnections in ultra-large scale integrated circuits, but probably would not be a valid criterion to test and perform effective diffusion barriers in a MIS capacitor stack. Indeed, the constraint in terms of impurity concentration is more drastic for stacks used in a MIS capacitor structure (electrical failure mode) than for an interconnection (metallurgical failure mode). More relevant electrical performance measurements of such stacks should be carried out.

However, it is well known that silicon nitride (Si₃N₄) is a non-absorptive material. Consequently the optical losses induced by a silicon nitride layer are limited. Also, HfO₂ and Al₂O₃ have band gaps above 5 eV and are therefore transparent in the infrared part of the spectrum. These materials can be considered as appropriate candidates to prevent metal diffusion within plasmon based devices. For large-scale integration there are also some considerations to be taken into account, such as low energy consumption and CMOS technology compatibility.

The thickness of the insulating diffusion barrier is directly related to the operating electrical power consumption of the surface plasmon device in FIGS. 1-A and 1-B. Indeed, the lower the thickness of the diffusion barrier in a MIS based structure, the lower the energy consumption as well as the operating voltage.

Indeed, MIS electro-optical devices are capacitance-operated devices, whose performance depends on the charge density ΔNₑ of the accumulated layer:

$$Δ {N}_{e} = {C}_{ox} \cdot \frac{{V}_{g} - {V}_{fb}}{{t}_{acc}} = \frac{{ɛ}_{StO 2} S}{EOT} \frac{{V}_{g} - {V}_{fb}}{{t}_{acc}}$$

Where Cₒₓ is the oxide capacitance, V_{g} is the applied voltage, V_{fb} is the flat band voltage and t is the thickness of the accumulated layer. ∈_{SiO2} is the dielectric constant of SiO₂, EOT is the equivalent oxide thickness of the gate insulator, and S is the surface of the latter. The EOT of an electrical insulator layer is the thickness of SiO₂ gate oxide needed to obtain the same gate capacitance as the one obtained with said electrical insulator layer.

If the capacitance is operated in the depletion or the inversion regime, a similar reasoning based on the variation of the accumulated charge as a function of the EOT of the gate insulator can be applied.

The introduction of a diffusion barrier in the MIS structure leads to an increase of equivalent oxide thickness. Thus, for a given level of performance, the formation of both, the electrical insulator layer 3 and the diffusion barrier layer 4 as thin as possible is needed in order to achieve low operation voltage and hence low energy consumption. Thus, advantageously, the specific material layer 4, in embodiments illustrated in FIGS. 1-A and 1-B, is less than 15 nm thick.

The investigated silicon nitride (LPCVD-SiN) based diffusion barriers have shown their effectiveness. However, the thicknesses of these diffusion barrier layers were in the range of 100 nm. Therefore, these layers can be considered too thick to be used in a MIS stack for surface plasmon devices. To use silicon nitride layers as diffusion barriers in this kind of device, it is important to experimentally test if a thin film of this material can effectively restrain the metallic diffusion in the MIS stack and hence to improve the electrical performance.

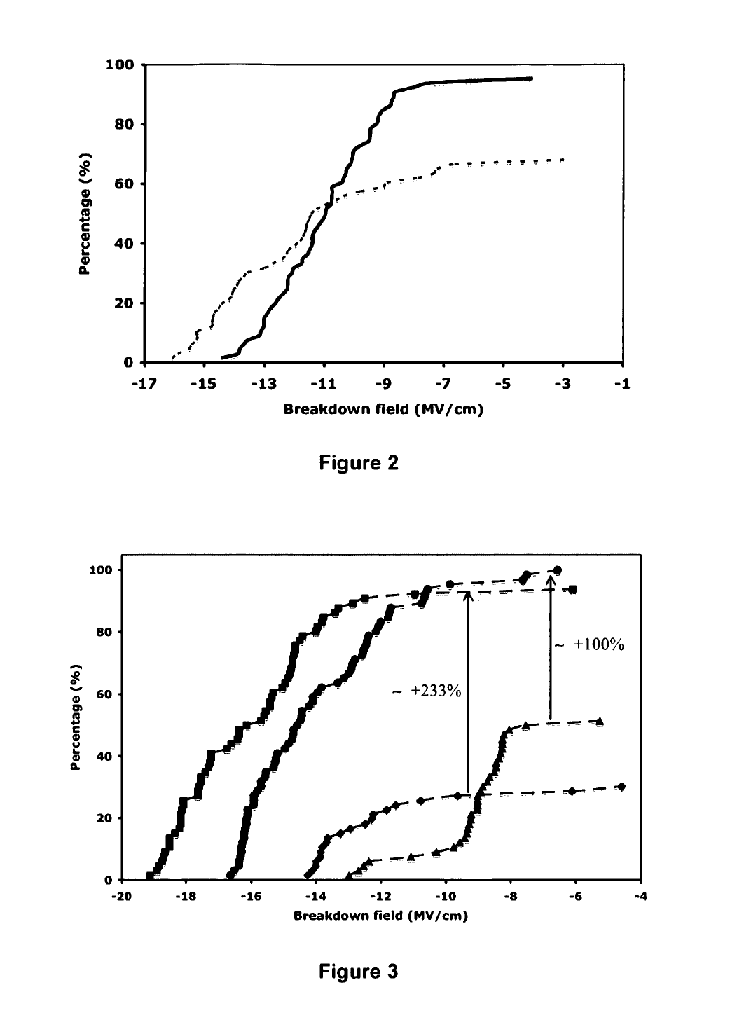

FIG. 2 illustrates cumulative breakdown field distributions of two different MIS stacks. These structures comprise a 10 nm thermal oxide layer deposited on a silicon substrate by annealing at 720° C. In the first stack, corresponding to the black line plot, a 3 nm silicon nitride (Si₃N₄) layer was deposited over the oxide layer via low pressure chemical vapor deposition (LPCVD) at a temperature of 625° C. Preferably, the deposited silicon nitride is a stoichiometric Si₃N₄. The metallic layers of these MIS stacks consist on 400 nm copper layers formed by physical vapor deposition. In the second stack, corresponding to the black dashed line plot, the metal layer was deposited directly over the oxide stack, while in the first stack it was deposited over the silicon nitride (Si₃N₄) layer.

The analysis of the cumulative distributions plotted in FIG. 2 shows that almost 100% of the devices comprising a silicon nitride (Si₃N₄) layer as diffusion barrier are operational with a minimum breakdown field of about −9 MV/cm (i.e. a minimum breakdown voltage of about −5V). In addition, almost 35% of the devices without silicon nitride layer do not work at the same threshold. These electrical reliability measurements show that a silicon nitride (Si₃N₄) based layer, having a thickness as low as 3 nm, can effectively prevent metal diffusion. Thus, silicon nitride (Si₃N₄) layers with this thickness can be used as a diffusion barrier in surface plasmon devices. Indeed, as mentioned above, silicon nitride is a transparent material in the infrared part of the spectrum and it can prevent metal diffusion even as a thin film. Therefore, silicon nitride appears to be an appropriate material to form a diffusion barrier that is electrically and optically compatible with surface plasmon devices.

As mentioned above, Al₂O₃ and HfO₂ may also appear as promising candidates to form diffusion barriers in surface plasmon devices. Indeed, these materials could form a thin diffusion barrier. In addition they have suitable optic characteristics that allow them to be included in a stack used in surface plasmon devices.

FIG. 3 illustrates cumulative breakdown field distributions of four different MIS stacks, using Al₂O₃, HfO₂ and Si₃N₄ based diffusion barriers. First and second structures include, respectively, a 6 nm HfO₂ layer and a 6 nm Al₂O₃ layer represented respectively by diamond symbol and triangle symbol in FIG. 3, which were deposited on a silicon substrate. Over these two layers, a 1.5 nm high thermal oxide (HTO) layer was deposited before copper layer formation. In order to realize third and fourth structures represented respectively by square symbol and circle symbol in FIG. 3, a 3 nm silicon nitride (Si₃N₄) layer was interposed between the Cu layer and the HTO layer in the first and second structures respectively. Preferably, the deposited silicon nitride is a stoichiometric Si₃N₄.

The analysis of the cumulative breakdown field distributions illustrated in FIG. 3 shows that almost 30% and 50% of devices comprising respectively HfO₂ and Al₂O₃ layers as diffusion barriers (diamond and triangle symbols) are operational with minimum breakdown field of about −7 MV/cm. In fact, only a small percentage of MIS stack based devices can withstand a high electrical field. Contrary to the Majumder et al. study results, these electrical reliability measurements show clearly that Al₂O₃ and HfO₂ based layers, even 6 nm thick, cannot effectively prevent Cu diffusion in the tested MIS capacitors.

Indeed, for this type of structure, the reliability breakdown voltage is one of the most sensitive measurements to detect metal contamination in MIS capacitors. It can detect levels of metal contamination in MIS stacks that can reach a concentration level much lower than using depth profiling techniques. Majumder et al shows that thin HfO₂ and Al₂O₃ dielectric can be used as a Cu diffusion barrier by detecting the metallurgical failure mode of the barrier. In these analysis the electrical barrier failure mode was tested.

In FIG. 3 breakdown field distributions of MIS stacks containing silicon nitride diffusion barriers were also plotted. With only a 3 nm thick silicon nitride layer interposed between the metal layer and HTO layer, a significant increase of the reliability at a fixed break down field is also achieved, for example at −7 MV/cm. This remarkable improvement in electrical reliability clearly shows that a thin silicon nitride layer can offer a more effective diffusion barrier allowing a lower defect density within the MIS stack based surface plasmon devices, than HfO₂ and Al₂O₃ layers.

The introduction of a silicon nitride film increases the stack thickness that is interposed between the copper layer and silicon layer. The fact that the stack is thicker could help prevention of copper atom penetration in the silicon layer. On the one hand, adding a silicon nitride layer to the stack increases its thickness by 40%. On the other hand, the reliability versus breakdown field increases by 233% and 100% (square and circle symbols) for MIS capacitors containing the added silicon nitride layer compared to MIS capacitors containing only HfO₂ and Al₂O₃ layer respectively (diamond and triangle symbols), for a given breakdown electric field. The increase in thickness between the metal layer and silicon layer cannot be the sole or main reason of the remarkable increase in electrical reliability.

Another indication against the thickness effect on reliability is given by the comparison of breakdown electrical field for a constant reliability level. Indeed the breakdown electrical field is taking into account some thickness effect by normalization of breakdown voltage by the EOT. Experimental data of FIG. 3 shows that for a given reliability level, for example 20%, stacks containing a silicon nitride (Si₃N₄) layer can withstand up to an 90% and 50% increase of the applied field compared to the MIS stacks containing only HfO₂ and Al₂O₃ diffusion barrier layer respectively. That behavior is particularly relevant to an improvement of the resistance of the stack, to ionic copper diffusion through the stack. In FIG. 3 achieving reliable operation at higher electrical field, i.e. independently from the thickness of the stack, when silicon nitride layer is used, means that the use of the latter material prevent early Cu diffusion in the stack.

Thus, we can deduce that stacks containing silicon nitride-based diffusion barriers are more electrically reliable than other stacks.

It is interesting to note that most studies found in literature concerning diffusion barriers of metals are realized in the sole aim to improve interconnection properties. As shown here, for large-scale integration of sensitive devices such as surface plasmon based devices, the introduction of diffusion barriers also improves electrical reliability of MIS capacitors.

Thin silicon nitride layers, less than 15 nm thick, can be used as diffusion barrier in surface plasmon devices. Thus, the specific material layer 4 of the embodiments of the invention illustrated in FIGS. 1-A and 1-B can be a silicon nitride (Si₃N₄) layer. As mentioned above, silicon nitride is advantageously a transparent material in the infrared part of the spectrum and it effectively prevents metallic diffusion. Therefore, silicon nitride could be among the most appropriate materials to form a diffusion barrier that is electrically and optically compatible with surface plasmon devices.

Moreover, it is well known that silicon nitride is widely used in microelectronic devices. It is a material compatible with standard CMOS technology, and it is ubiquitous in CMOS foundries.

1. An electro-optical device comprising successively:
a semiconductor layer;
a silicon oxide layer;
a silicon nitride layer;
a first metal layer;
wherein the silicon nitride layer is less than 15 nm thick and disposed so as to provide an interface between the first metal layer and the silicon oxide layer, and wherein the electro-optical device is configured to carry a plasmonic wave.

2. The electro-optical device of claim 1, wherein a second metal layer is disposed adjacent the semiconductor layer on the opposite side of the first metal layer.

3. The electro-optical device of claim 1, wherein the semiconductor and the first metal layers are configured as electric contacts, and the electro optical device is configured to alter the propagation properties of a plasmonic wave in response to the application of an electrical field across the first metal layer and the semiconductor layer.

4. The electro-optical device of claim 2, wherein the first and the second metal layers are configured as electric contacts, and the electro-optical device is configured to alter the propagation properties of a plasmonic wave in response to the application of an electrical field across the first and the second metal layers.

5. The electro-optical device of claim 1, wherein the semiconductor layer comprises silicon.

6. (canceled)

7. (canceled)

8. The electro-optical device of claim 1, wherein the first metal layer comprises a material selected in the group consisting of gold, silver, copper and aluminum.
